(19) United States
(12) Patent Application Publication
(10) Pub. No.: US 2005/0274988 A1
(43) Pub. Date: Dec. 15, 2005

(54) Imager with reflector mirrors

(76) Inventor: Sungkwon C. Hong, Boise, ID (US)

Correspondence Address: DICKSTEIN SHAPIRO MORIN & OSHINSKY LLP, 2101 L Street, NW, Washington, DC, 20037, US

(21) Appl. No.: 10/856,932

(22) Filed: Jun. 1, 2004

(51) Int. Cl. H01L 27/148

(52) U.S. Cl. 257/225

(57) ABSTRACT

Embodiments of the invention provide an imager pixel comprising a reflective layer formed over a substrate. There is a semiconductor layer over the reflective layer. A photo-conversion device is formed at a surface of the semiconductor layer. The reflective layer serves to reflect incident light not initially absorbed into the photo-conversion device, back to the photo-conversion device.

### FIELD OF THE INVENTION

The present invention relates to the field of semiconductor devices, particularly to an imager pixel with improved quantum efficiency and reduced cross talk.

### BACKGROUND OF THE INVENTION

Typically, an image sensor array includes a focal plane array of pixels, each one of the pixels including a photo-conversion device such as, e.g., a photogate, photoconductor, or a photodiode. FIG. 1 illustrates a typical CMOS imager pixel 10 having a pinned photodiode 21 as its photo-conversion device. The photodiode 21 is adjacent to an isolation region 13, which is depicted as a shallow trench isolation (STI) region. The photodiode 21 includes an n-type region 11 underlying a p+ surface layer 12.

The photodiode 21 converts photons to charge carriers, e.g., electrons, which are transferred to a floating diffusion region 15 by a transfer transistor 24. In addition, the illustrated pixel 10 typically includes a reset transistor 25, connected to a source/drain region 16, for resetting the floating diffusion region 15 to a predetermined charge level prior to charge transference. In operation, a source follower transistor (not shown) outputs a voltage representing the charge on the floating diffusion region 15 to a column line (not shown) when a row select transistor (not shown) for the row containing the pixel is activated.

Exemplary CMOS image sensor circuits, processing steps thereof, and detailed descriptions of the functions of various CMOS elements of an image sensor circuit are described, for example, in U.S. Pat. No. 6,140,630, U.S. Pat. No. 6,376,868, U.S. Pat. No. 6,310,366, U.S. Pat. No. 6,326,652, U.S. Pat. No. 6,204,524, and U.S. Pat. No. 6,333,205, assigned to Micron Technology, Inc. The disclosures of each of the forgoing patents are herein incorporated by reference in their entirety.

In the conventional pixel 10, when incident light strikes the surface of the photodiode 21, charge carriers (electrons), are generated in the depletion region of the p-n junction (between region 11 and region 12) of the photodiode 21. The carriers are collected in the region 11. Light having shorter wavelengths, e.g., 650 nanometers (nm) or shorter, (represented by arrows 18) is absorbed closer to the surface of the substrate 1, whereas light having longer wavelengths, e.g., 650-750 nm or longer, (represented by arrows 17) is absorbed deeper into the substrate 1. In the conventional pixel 10 of FIG. 1, a large amount of incident light of longer wavelengths will not be absorbed in the photodiode 21 leading to decreased quantum efficiency. In order to capture light absorbed deep in the substrate 1, the depletion region of the photodiode 21 would have to be very deep, e.g., tens of microns deep. Such a design, however, can lead to increased cross talk, where charge carriers from one pixel travel to adjacent pixels. This approach also requires complicated fabrication processes. What is needed, therefore, is a pixel that can capture longer wavelengths of light, e.g., 650-750 nm or longer, with improved quantum efficiency and without increased cross talk.

### BRIEF SUMMARY OF THE INVENTION

Embodiments of the invention provide an imager pixel comprising a reflective layer formed over a substrate. There is a semiconductor layer over the reflective layer. A photo-conversion device is formed at a surface of the semiconductor layer. The reflective layer serves to reflect incident light, not initially absorbed into the photo-conversion device, back to the photo-conversion device. Thereby, the quantum efficiency of the pixel can be improved. Also, cross talk can be reduced as reflected light will not travel to adjacent pixels.

### BRIEF DESCRIPTION OF THE DRAWINGS

The foregoing and other advantages and features of the invention will become more apparent from the detailed description of exemplary embodiments provided below with reference to the accompanying drawings in which:

FIG. 1 is a cross-sectional view of a conventional pixel;

FIG. 2 is a cross-sectional view of a pixel according to an embodiment of the invention;

FIG. 3 is a cross-sectional view of a portion of the FIG. 2 pixel;

FIG. 4 is a cross-sectional view of the FIG. 2 pixel at an initial stage of fabrication;

FIGS. 5-10 are cross-sectional views of the FIG. 2 pixel at intermediate stages of fabrication;

FIG. 11 is a block diagram of an image sensor according to an embodiment of the invention; and

FIG. 12 is a block diagram of a processing system according to an embodiment of the invention.

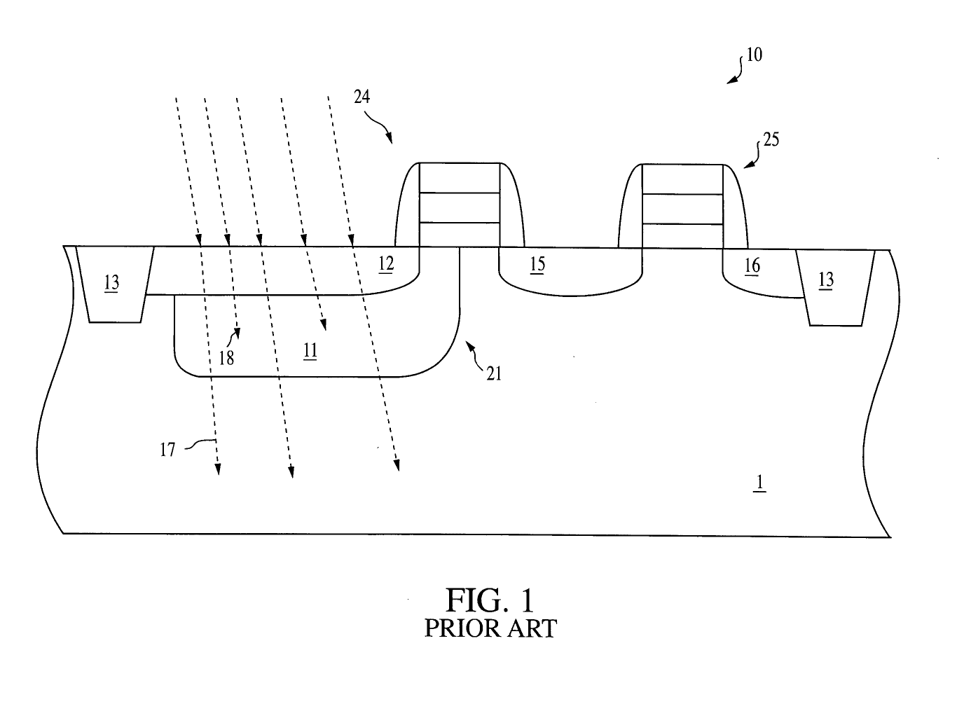

### DETAILED DESCRIPTION OF THE INVENTION

In the following detailed description, reference is made to the accompanying drawings, which form a part hereof and illustrate specific embodiments in which the invention may be practiced. In the drawings, like reference numerals describe substantially similar components throughout the several views. These embodiments are described in sufficient detail to enable those skilled in the art to practice the invention, and it is to be understood that other embodiments may be utilized, and that structural, logical and electrical changes may be made without departing from the spirit and scope of the present invention.

The terms “wafer” and “substrate” are to be understood as including silicon, silicon-on-insulator (SOI), or silicon-on-sapphire (SOS) technology, doped and undoped semiconductors, epitaxial layers of silicon supported by a base semiconductor foundation, and other semiconductor structures. Furthermore, when reference is made to a “wafer” or “substrate” in the following description, previous process steps may have been utilized to form regions or junctions in the base semiconductor structure or foundation. In addition, the semiconductor need not be silicon-based, but could be based on silicon-germanium, germanium, or gallium-arsenide.

The term “pixel” refers to a picture element unit cell containing a photo-conversion device for converting electromagnetic radiation to an electrical signal. For purposes of illustration, a representative pixel is illustrated in the figures and description herein, and typically fabrication of all pixels in an image sensor will proceed concurrently in a similar fashion.

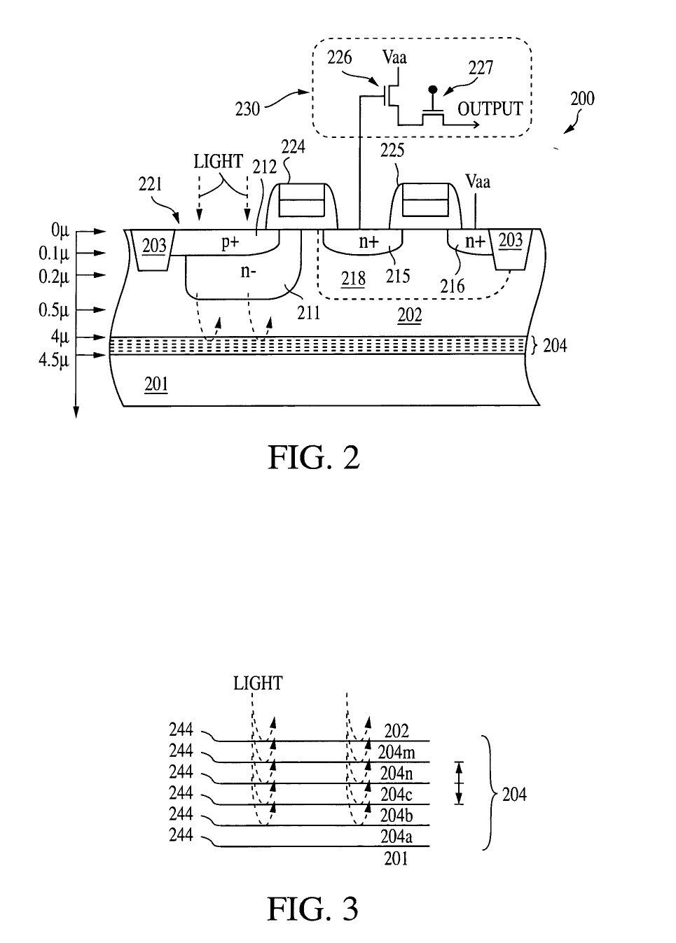

Referring to the drawings, FIG. 2 depicts a pixel 200 according to an exemplary embodiment of the invention. Pixel 200 includes a photo-conversion device, which is, illustratively, a pinned photodiode 221. The photodiode 221 is adjacent to an isolation region 203, which is illustratively a shallow trench isolation (STI) region. The photodiode 221 includes an n-type region 211 underlying a p+ surface layer 212. Adjacent to the photodiode 221, is a floating diffusion region 215. Between the photodiode 221 and the floating diffusion region 215 is a transfer transistor 224, which operates to transfer charge from the photodiode 221 to the floating diffusion region 215.

It should be noted that the configuration of pixel 200 is only exemplary and that various changes may be made as are known in the art and pixel 200 may have other configurations. Although the invention is described in connection with a four-transistor (4T) pixel, the invention may also be incorporated into other pixel circuits having different numbers of transistors. Without being limiting, such a circuit may include a three-transistor (3T) pixel, a five-transistor (5T) pixel, and a six-transistor (6T) pixel. A 3T cell omits the transfer transistor, but may have a reset transistor adjacent to a photodiode. A 5T pixel differs from the 4T pixel by the addition of a transistor, such as a shutter transistor or a CMOS photogate transistor, and a 6T pixel further includes an additional transistor, such as an anti-blooming transistor.

A readout circuit 230 is connected to the floating diffusion region 215. The readout circuit 230 includes a source follower transistor 226, the gate of which is connected to the floating diffusion region 215. The readout circuit also includes a row select transistor 227 for selecting the pixel 200 for readout in response to a signal received at the gate of the row select transistor 227.

A reset transistor 225 is provided adjacent to the floating diffusion region 215. In response to a signal received at the reset transistor 225 gate, the reset transistor 225 resets the floating diffusion region 215 to a predetermined voltage, which is, for example, an array voltage Vaa. The source/drain region 216 of the reset transistor 225 is connected to Vaa and is adjacent to an STI region 203.

As shown in FIG. 2, the transfer and reset transistors 224, 225, and photodiode 221 are located at a surface of a semiconductor layer 202. Illustratively, the semiconductor layer 202 is a layer of p-type silicon (Si). A doped well 218 can be formed within the Si layer 202. In the exemplary embodiment of FIG. 2, well 218 is a p-well. The p-well 218 extends from the surface of Si layer 202 to a depth within Si layer 202, e.g., a depth greater than the n-type region 211. The p-well 218 reaches from below an STI region 203 adjacent to the source/drain region 216 of the reset transistor 225 to a point below the transfer transistor 224. Accordingly, the source/drain region 216 and floating diffusion region 215 are located in the p-well 218.

The Si layer 202 overlies a reflective layer 204, which in turn overlies a substrate 201. As shown in FIG. 3, the reflective layer 204 is illustratively a Distributed Bragg Reflector (DBR) mirror including sub-layers 204a, 204b, 204c, 204n, and 204m. Reflective layer 204, however, can include more or fewer sub-layers. Sub-layers 204b and 204n each have a first index of refraction. Illustratively, Si layer 202 and substrate 201 also have the first index of refraction. Sub-layers 204a, 204c, and 204m each have a second index of refraction. Therefore, each sub-layer 204a-m is in contact with material having a different refractive index to form a (first refractive index layer)/(second refractive index layer) structure. For example, sub-layer 204c has a first refractive index and is in contact with overlying sub-layer 204n and underlying sub-layer 204b, each having a second refractive index. Similarly, sub-layer 204n contacts overlying sub-layer 204m and underlying sub-layer 204c, which each have a first index of refraction.

In the exemplary embodiment of FIGS. 2-3, the sub-layers 204a-m are dielectric and/or semiconductor materials. According to one exemplary embodiment, sub-layers 204b and 204n are silicon (Si) and sub-layers 204a, 204c, and 204m are silicon-germanium (SiₓGe₁₋ₓ), such that reflective layer 204 has an SiₓGe₁₋ₓ/Si structure. In another exemplary embodiment, sub-layers 204b and 204n are Si and sub-layers 204a, 204c, and 204m are SiO₂, such that reflective layer 204 has an SiO₂/Si structure.

Each set of sub-layers which makes up the structural pattern of reflective layer 204 has a thickness T. For example, as shown in FIG. 3, a pair of adjacent sub-layers (one sub-layer having the first refractive index and another sub-layer having the second refractive index) has a thickness T. Illustratively, the sub-layers 204a-m are stacked such that the (first refractive index sub-layer)/(second refractive index sub-layer) structure is periodic, or otherwise stated the reflective layer 204 has a (first refractive index sub-layer)/(second refractive index sub-layer) periodic structure. In the exemplary embodiment of FIGS. 2 and 3, T, the thickness or period of the structure, is approximately equal to one quarter of the wavelength targeted for reflection. Otherwise stated, to optimize the reflection for a desired wavelength λ, T is approximately equal to λ/4. For example, where the wavelength of light targeted for reflection by reflective layer 204 is approximately 650 to 750 nanometers (nm) (a red light signal), the period T of the (first refractive index layer)/(second refractive index layer) structure is approximately 175 nm.

Light of a targeted wavelength (represented by dashed arrows) incident on photodiode 221, which is not initially absorbed into photodiode 221, is reflected by the reflective layer 204, as shown in FIGS. 2 and 3. Light is reflected at the discontinuity at the junctions 244 between the sub-layers 204a-m, where materials having differing refractive indexes meet. The total reflectivity of reflective layer 204 is a summation of the reflections from each of the junctions 244. Thereby, the quantum efficiency of the pixel 200 is increased as compared to a conventional pixel 10. Additionally, cross talk can be reduced, as the reflected light will not travel to adjacent pixels. Further, the thickness of the Si layer 202 can be effectively reduced because a thick Si layer 202 is not needed to accommodate a deep depletion region.

The number of sub-layers in layer 204 and the materials used to form the sub-layers can be optimized to produce a highly reflective DBR mirror at a targeted wavelength. At the targeted wavelength, the optimal number of sub-layers will depend on the difference in the refractive indexes of the chosen materials.

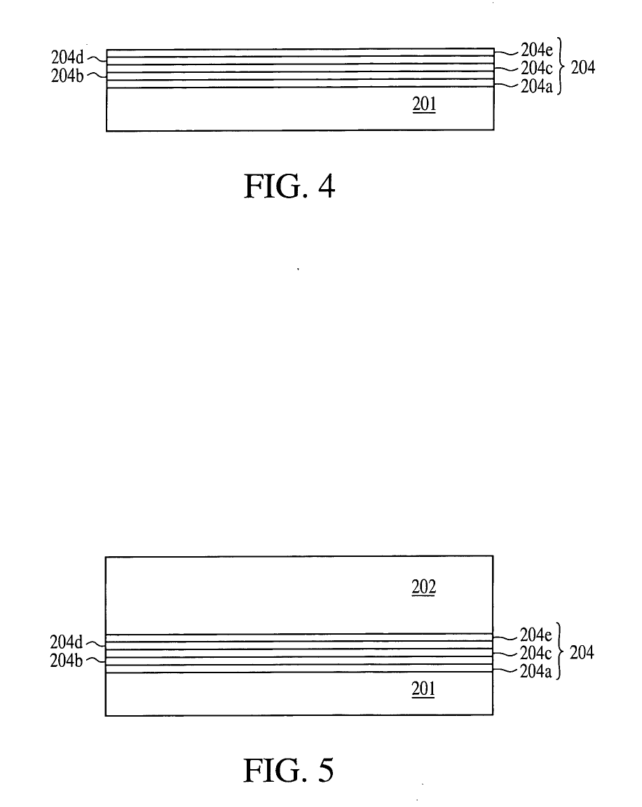

Exemplary embodiments for the fabrication of the pixel 200 are described below with reference to FIGS. 4 through 10. No particular order is required for any of the actions described herein, except for those logically requiring the results of prior actions. Accordingly, while the actions below are described as being performed in a general order, the order is exemplary only and may be altered.

FIG. 4 illustrates a pixel cell 200 at an initial stage of fabrication. In one exemplary embodiment, alternating sub-layers of SiₓGe₁₋ₓ and Si are formed on the substrate 201 to form reflective layer 204. Illustratively, for the SiₓGe₁₋ₓ sub-layers, x can be within the range of approximately 0.8 to approximately 0.95. The reflective layer 204 can be formed having a thickness of approximately 0.5 micrometers (μm). As shown in FIG. 4, sub-layers 204a, 204c, and 204m are SiₓGe₁₋ₓ sub-layers and sub-layers 204b and 204n are Si sub-layers. As noted above, layer 204 can be formed having an SiₓGe₁₋ₓ/Si structure with a period of approximately λ/4. Each of the sub-layers 204a-m can be formed by methods known in the art, such as, for example, epitaxy, chemical vapor deposition (CVD), and atomic layer deposition (ALD).

As shown in FIG. 5, Si layer 202 is grown or deposited on reflective layer 204. Si layer 202 is of a first conductivity type, which in the illustrated embodiment is p-type, and can be formed having a thickness of approximately 4 μm.

Alternatively, in another exemplary embodiment, layer 204 can be formed having an SiO₂/Si structure. In such a case sub-layers 204a, 204c, and 204m are SiO₂ sub-layers and sub-layers 204b and 204n are Si sub-layers. The SiO₂/Si structure can be formed using known SOI techniques, such as, for example, wafer bonding techniques, where two oxidized Si wafers are bonded and the excess Si from one of the wafers is removed; or implantation techniques, where oxygen is implanted into a Si wafer, to achieve the structure shown in FIG. 5. Where wafer bonding techniques are used, substrate 201 and Si layer 202 would be Si wafers. Where implantation techniques are used substrate 201 and Si layer 202 would be a same Si wafer. As noted above, layer 204 can be formed having an SiO₂/Si structure with a period of approximately λ/4.

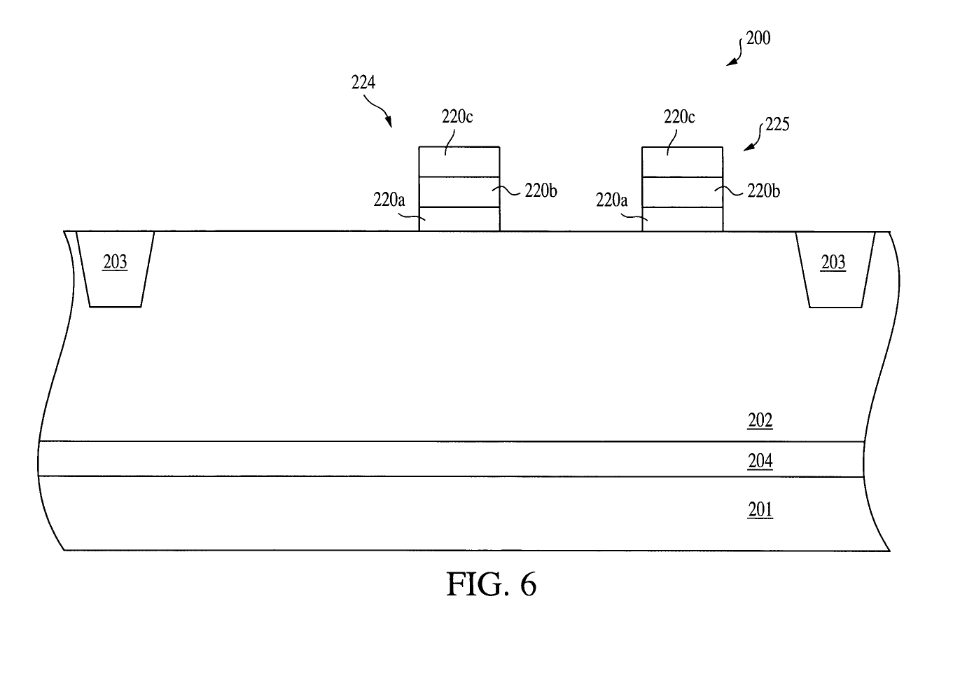

FIG. 6 depicts the formation of isolation regions 203 and the transistor 224, 225 gate stacks. Although not shown, the source follower and row select transistors 226, 227 can be formed concurrently with the transfer and reset transistors 224, 225 as described below.

The isolation regions 203 are formed in the Si layer 202 and filled with a dielectric material. The dielectric material may be an oxide material, for example a silicon oxide, such as SiO or SiO₂; oxynitride; a nitride material, such as silicon nitride; silicon carbide; a high temperature polymer; or other suitable dielectric material. As shown in FIG. 6, the isolation regions 203 can be STI regions and can have a depth of approximately 0.2 μm. The dielectric material is illustratively a high density plasma (HDP) oxide, a material which has a high ability to effectively fill narrow trenches.

To form the transfer and reset transistor 224, 225 gate stacks, as shown in FIG. 6, a first insulating layer 220a of, for example, silicon oxide is grown or deposited on the Si layer 202. The first insulating layer 220a serves as the gate oxide layer for the subsequently formed transistor gates 224 and 225. Next, a layer of conductive material 220b is deposited over the oxide layer 220a. The conductive layer 220b serves as the gate electrode for the subsequently formed transistors 224, 225. The conductive layer 220b may be a layer of polysilicon, which may be doped to a second conductivity type, e.g., n-type. A second insulating layer 220c is deposited over the polysilicon layer 220b. The second insulating layer 220c may be formed of, for example, an oxide (SiO₂), a nitride (silicon nitride), an oxynitride (silicon oxynitride), ON (oxide-nitride), NO (nitride-oxide), or ONO (oxide-nitride-oxide).

The layers 220a, 220b, and 220c, may be formed by conventional deposition methods, such as chemical vapor deposition (CVD) or plasma enhanced chemical vapor deposition (PECVD), among others. The layers 220a, 220b, and 220c are then patterned and etched to form the transfer and reset transistor 224, 225 multilayer gate stack structures shown in FIG. 6.

The invention is not limited to the structure of the gate stacks described above. Additional layers may be added or the gate stacks may be altered as is desired and known in the art. For example, a silicide layer (not shown) may be formed between the gate electrodes 220b and the second insulating layers 220c. The silicide layer may be included in the transfer and reset transistor 224, 225 gate stacks, or in all of the transistor gate structures in an image sensor circuit, and may be titanium silicide, tungsten silicide, cobalt silicide, molybdenum silicide, or tantalum silicide. This additional conductive layer may also be a barrier layer/refractor metal, such as TiN/W or W/Nₓ/W, or it could be formed entirely of WNₓ.

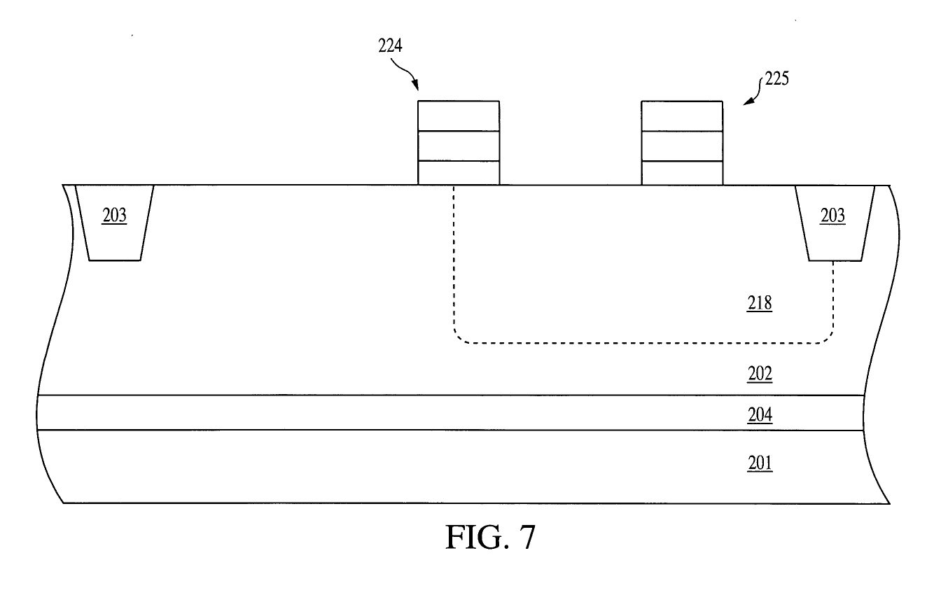

A well 218 of the first conductivity type, illustratively a p-well, is implanted into the Si layer 202 as shown in FIG. 7. The p-well 218 is formed in the Si layer 202 from a point below the transfer gate 224 to a point below the STI region 203 that is on a side of the reset gate 225 opposite the transfer gate 224. The p-well 218 may be formed by known methods. For example, a layer of photoresist (not shown) can be patterned over the Si layer 202 having an opening over the area where a p-well 218 is to be formed. A p-type dopant, such as boron, can be implanted into the substrate through the opening in the photoresist. Illustratively, the p-well 218 is formed having a p-type dopant concentration that is higher than adjacent portions of the Si layer 202.

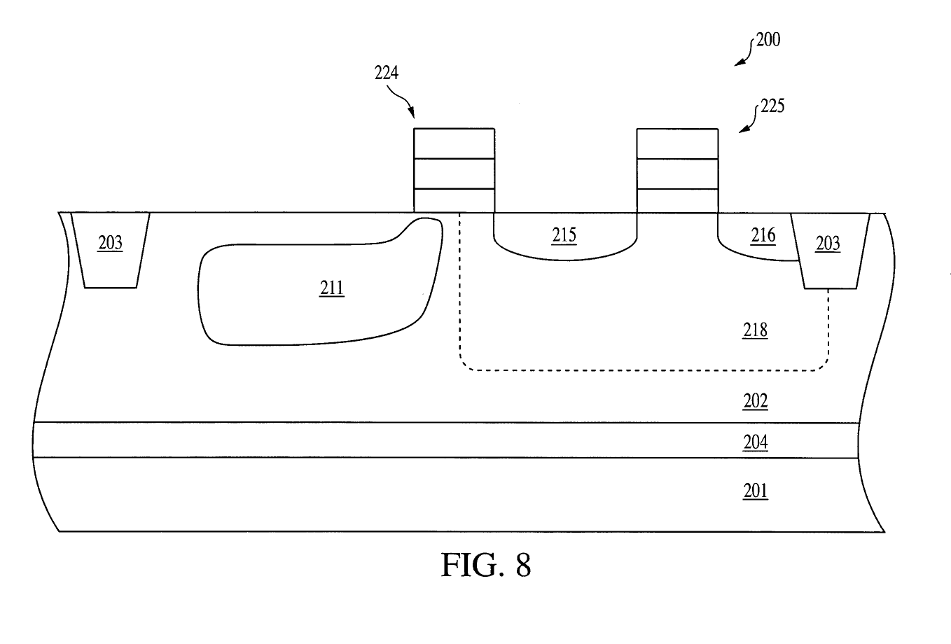

As depicted in FIG. 8, a doped region 211 of the second conductivity type is implanted in the Si layer 202 (for the photodiode 221). The doped region 211 is, illustratively, a lightly doped n-type region formed to a depth of approximately 0.5 μm. For example, a layer of photoresist (not shown) may be patterned over the Si layer 202 having an opening over the surface of the Si layer 202 where pinned photodiode 221 is to be formed. An n-type dopant, such as phosphorus, arsenic, or antimony, may be implanted through the opening and into the Si layer 202. Multiple implants may be used to tailor the profile of region 211. If desired, an angled implantation may be conducted to form the doped region 211, such that implantation is carried out at angles other than 90 degrees relative to the surface of the Si layer 202.

As shown in FIG. 8, the region 211 is formed on an opposite side of the transfer gate 224 from the reset gate 225 and is approximately aligned with an edge of the gate of the transfer transistor 224. Region 211 forms a photosensitive charge accumulating region for collecting photo-generated charge.

The floating diffusion region 215 and the reset transistor 225 source/drain region 216 may be implanted by known methods to achieve the structure shown in FIG. 8. The floating diffusion region 215 and source/drain region 216 are formed as regions of the second conductivity type, which for exemplary purposes is n-type. Any suitable n-type dopant, such as phosphorus, arsenic, or antimony, may be used. The floating diffusion region 215 is formed between the transfer transistor 224 gate stack and the reset transistor 225 gate stack. The reset source/drain region 216 is formed adjacent to the reset transistor 225 gate stack and opposite to the floating diffusion region 215.

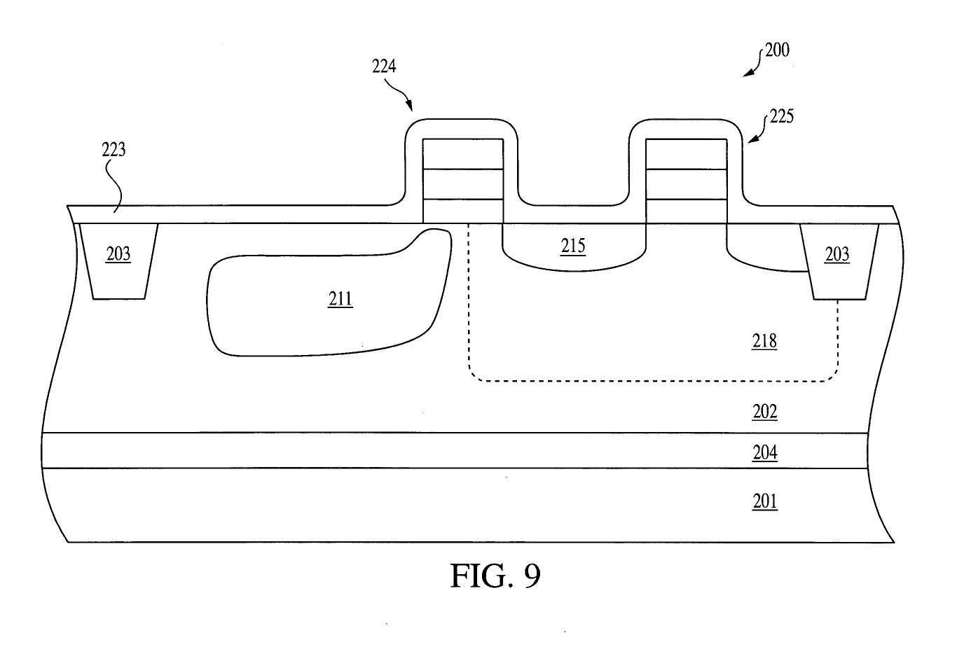

FIG. 9 depicts the formation of a dielectric layer 223. Illustratively, layer 223 is an oxide layer, but layer 223 may be any appropriate dielectric material, such as silicon dioxide, silicon nitride, an oxynitride, ON, NO, ONO, or TEOS, among others, formed by methods known in the art.

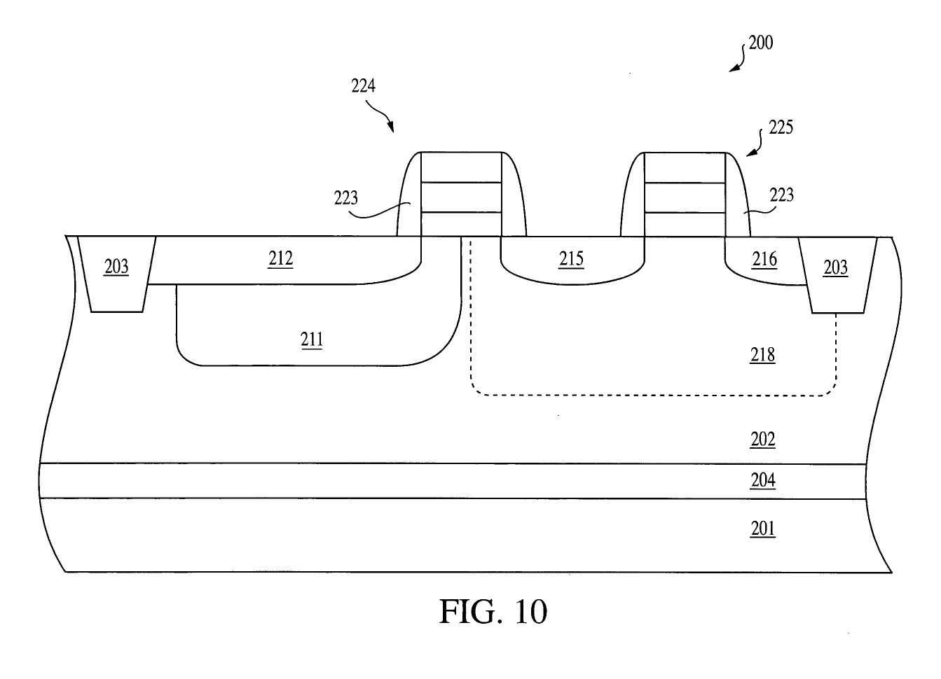

The doped surface layer 212 for the photodiode 221 is implanted, as illustrated in FIG. 10. Doped surface layer 212 is doped to the first conductivity type. Illustratively, doped surface layer 212 is a highly doped p+ surface layer and is formed to a depth of approximately 0.1 μm. A p-type dopant, such as boron, indium, or any other suitable p-type dopant, may be used to form the p+ surface layer 212.

The p+ surface layer 212 may be formed by known techniques. For example, layer 212 may be formed by implanting p-type ions through openings in a layer of photoresist. Alternatively, layer 212 may be formed by a gas source plasma doping process, or by diffusing a p-type dopant into the Si layer 202 from an in-situ doped layer or a doped oxide layer deposited over the area where layer 212 is to be formed.

Also, as shown in FIG. 10, a dry etch step is conducted to etch portions of the oxide layer 223 such that only sidewall spacers 223 on gates 224 and 225 remain. Alternatively, oxide layer 223 may be etched such that remaining portions form a sidewall spacer 223 on a sidewall of reset gate 225 opposite to floating diffusion region 215 and a protective layer (not shown) over the transfer gate 224, the photodiode 221, the floating diffusion region 215 and a portion of the reset gate 225 adjacent to the floating diffusion region 215.

Conventional processing methods may be used to complete the pixel 200. For example, insulating, shielding, and metallization layers to connect gate lines, and other connections to the pixel 200 may be formed. Also, the entire surface may be covered with a passivation layer (not shown) of, for example, silicon dioxide, BSG, PSG, or BPSG, which is CMP planarized and etched to provide contact holes, which are then metallized to provide contacts. Conventional layers of conductors and insulators may also be used to interconnect the structures and to connect pixel 200 to peripheral circuitry.

While the above embodiments are described in connection with the formation of pnp-type photodiodes the invention is not limited to these embodiments. The invention also has applicability to other types of photo-conversion devices, such as a photodiode formed from np or npn regions in a substrate, a photogate, or a photoconductor. If an npn-type photodiode is formed the dopant and conductivity types of all structures would change accordingly.

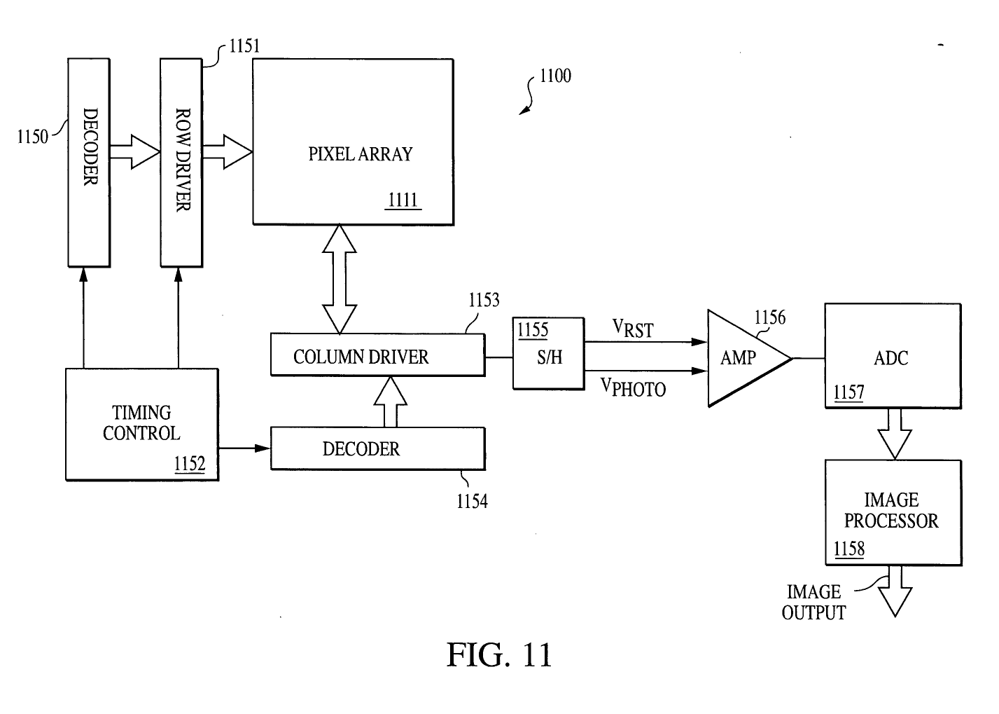

A typical single chip CMOS image sensor 1100 is illustrated by the block diagram of FIG. 11. The image sensor 1100 has a pixel array 1111 containing a plurality of pixel cells arranged in rows and columns. The array 1111 includes one or more pixels 200 as described above in connection with FIGS. 2-10.

The pixels of each row in array 1111 are all turned on at the same time by a row select line, and the pixel signals of each column are selectively output by respective column select lines. The row lines are selectively activated by a row driver 1151 in response to row address decoder 1150. The column select lines are selectively activated by a column driver 1153 in response to column address decoder 1154. The pixel array is operated by the timing and control circuit 1152, which controls address decoders 1150, 1154 for selecting the appropriate row and column lines for pixel signal readout.

The signals on the column readout lines typically include a pixel reset signal (Vᵣₛₜ) and a pixel image signal (Vₚₕₒₜₒ) for each pixel. Both signals are read into a sample and hold circuit (S/H) 1155 associated with the column driver 1153. A differential signal (Vᵣₛₜ−Vₚₕₒₜₒ) is produced by differential amplifier (AMP) 1156 for each pixel, and each pixel's differential signal is amplified and digitized by analog to digital converter (ADC) 1157. The analog to digital converter 1157 supplies the digitized pixel signals to an image processor 1158 which performs appropriate image processing before providing digital signals defining an image.

Although the invention is described in connection with a CMOS image sensor 1100, the invention is also applicable to analogous structures of a charge coupled device (CCD) image sensor.

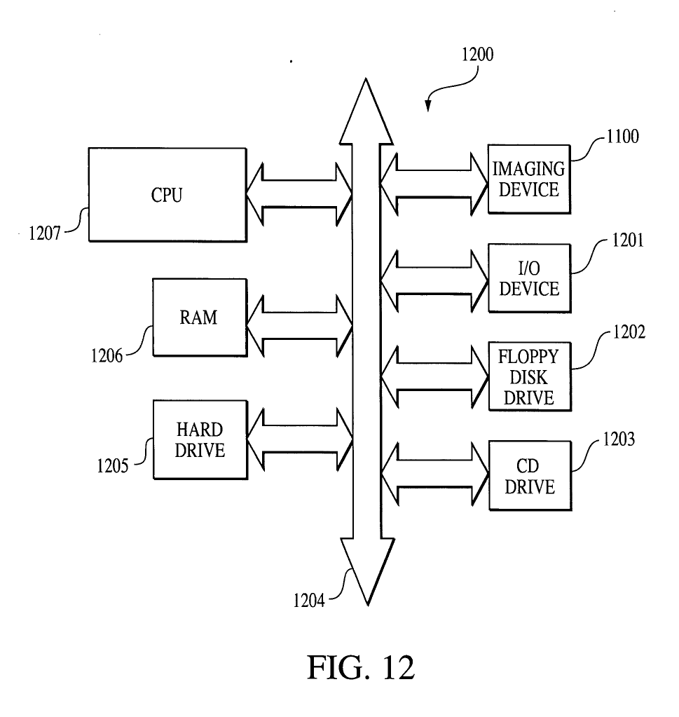

FIG. 12 illustrates a processor-based system 1200 including the image sensor 1100 of FIG. 11. The processor-based system 1200 is exemplary of a system having digital circuits that could include CMOS image sensor devices. Without being limiting, such a system could include a computer system, camera system, scanner, machine vision, vehicle navigation, video phone, surveillance system, auto focus system, star tracker system, motion detection system, image stabilization system, and data compression system.

The processor-based system 1200, for example a computer system, generally comprises a central processing unit (CPU) 1207, such as a microprocessor, that communicates with an input/output (I/O) device 1201 over a bus 1204. Image sensor 1100 also communicates with the CPU 1207 over bus 1204. The processor-based system 1200 also includes random access memory (RAM) 1206, and may include peripheral devices, such as a floppy disk drive 1202 and a compact disk (CD) ROM drive 1203, which also communicate with CPU 1207 over the bus 1204. Image sensor 1100 may be combined with a processor, such as a CPU, digital signal processor, or microprocessor, with or without memory storage on a single integrated circuit or on a different chip than the processor.

It is again noted that the above description and drawings are exemplary and illustrate preferred embodiments that achieve the objects, features and advantages of the present invention. It is not intended that the present invention be limited to the illustrated embodiments. Any modification of the present invention which comes within the spirit and scope of the following claims should be considered part of the present invention.

1. A pixel cell comprising:
a substrate;
a reflective layer over the substrate, the reflective layer comprising a plurality of first sub-layers each having a first refractive index and at least one second sub-layer having a second refractive index, the plurality of first sub-layers stacked alternately with the at least one second sub-layer;
a semiconductor layer over the reflective layer;
a photo-conversion device at a surface of the semiconductor layer for receiving light reflected by the reflective layer and for generating charge in response to the reflected light.

2. The pixel cell of claim 1, wherein the reflective layer is approximately 0.5 μm thick.

3. The pixel cell of claim 1, wherein the reflective layer has a periodic structure.

4. The pixel cell of claim 3, wherein the reflective layer has a first sub-layer/second sub-layer periodic structure.

5. The pixel cell of claim 4, wherein the reflected light has a wavelength λ, and a period of the first sub-layer/second sub-layer structure is approximately λ/4.

6. The pixel cell of claim 4, wherein the reflected light has a wavelength within the range of approximately 650 nm to 750 nm, and a period of the first sub-layer/second sub-layer structure is approximately 175 nm.

7. The pixel cell of claim 1, wherein each of the first and the second sub-layers are one of a semiconductor material and a dielectric material.

8. The pixel cell of claim 1, wherein each of the first sub-layers are SiₓGe₁₋ₓ and the at least one second sub-layer is Si.

9. The pixel of claim 8, wherein x is within the range of approximately 0.8 to approximately 0.95.

10. The pixel cell of claim 1, wherein each of the first sub-layers are SiO₂ and the at least one second sub-layer is Si.

11. The pixel of claim 1, wherein the reflective layer is a Distributed Bragg Reflector mirror.

12. The pixel cell of claim 1, further comprising a plurality of second sub-layers.

13. A pixel cell comprising:
a substrate;
a plurality of layers of SiₓGe₁₋ₓ;
a plurality of layers of Si, the plurality of SiₓGe₁₋ₓ layers stacked alternately with the plurality of Si layers to form an SiₓGe₁₋ₓ/Si structure over the substrate;
a semiconductor layer over the stacked plurality of SiₓGe₁₋ₓ layers and plurality of Si layers; and
a photo-conversion device at a surface of the semiconductor layer for receiving light reflected by the first and second reflective layers and for generating charge in response to the reflected light.

14. The pixel cell of claim 13, wherein the combined thickness of one SiₓGe₁₋ₓ layer and one Si layer stacked in contact with each other is approximately equal to λ/4, where λ is a predetermined wavelength of the reflected light.

15. A pixel cell comprising:
a substrate;
a plurality of layers of SiO₂;
a plurality of layers of Si, the plurality of SiO₂ layers stacked alternately with the plurality of Si layers to form an SiO₂/Si structure over the substrate;
a semiconductor layer over the stacked plurality of SiO₂ layers and plurality of Si layers; and
a photo-conversion device at a surface of the semiconductor layer for receiving light reflected by the first and second reflective layers and for generating charge in response to the reflected light.

16. The pixel cell of claim 15, wherein the combined thickness of one SiO₂ layer and one Si layer stacked in contact with each other is approximately equal to λ/4, where λ is a predetermined wavelength of the reflected light.

17. An image sensor comprising:
a substrate;
a reflective layer over the substrate, the reflective layer comprising a plurality of first sub-layers each having a first refractive index and at least one second sub-layer having a second refractive index;
a semiconductor layer over the reflective layer;
an array of pixel cells at a surface of the semiconductor layer, each pixel comprising a photo-conversion device for receiving light reflected from the reflective layer and for generating charge in response to the reflected light.

18. The image sensor of claim 17, wherein the reflective layer has a periodic structure.

19. The image sensor of claim 17, wherein the reflective layer has a first sub-layer/second sub-layer periodic structure.

20. The image sensor of claim 19, wherein the reflected light has a wavelength λ, and a period of the first sub-layer/second sub-layer structure is approximately λ/4.

21. The image sensor of claim 17, wherein each of the first and the at least one second sub-layers are one of a semiconductor material and a dielectric material.

22. The image sensor of claim 17, wherein each of the first sub-layers are SiₓGe₁₋ₓ and the at least one second sub-layer is Si.

23. The image sensor of claim 17, wherein each of the first sub-layers are SiO₂ and the at least one second sub-layer is Si.

24. The image sensor of claim 17, further comprising a plurality of second sub-layers.

25. The image sensor of claim 17, wherein the reflective layer is a Distributed Bragg Reflector mirror.

26. A processor system comprising:
a processor; and
an image sensor coupled to the processor, the image sensor comprising:
a substrate;
a reflective layer over the substrate, the reflective layer comprising a plurality of first sub-layers each having a first refractive index and at least one second sub-layer having a second refractive index;
a semiconductor layer over the reflective layer; and
an array of pixel cells at a surface of the semiconductor layer, each pixel comprising a photo-conversion device for receiving light reflected from the reflective layer and for generating charge in response to the reflected light.

27. The processor system of claim 26, wherein the image sensor is a CMOS image sensor.

28. The processor system of claim 26, wherein the image sensor is a Charge Coupled Device image sensor.

29. A method of forming a pixel cell, the method comprising the acts of:
forming a reflective layer over a substrate by alternately forming a plurality of first sub-layers having a first refractive index and at least one second sub-layer having a second refractive index;
providing a semiconductor layer over the reflective layer; and
forming a photo-conversion device at a surface of the semiconductor layer for receiving light reflected from the reflective layer and for generating charge in response to the reflected light.

30. The method of claim 29, wherein the act of forming the reflective layer comprises forming the reflective layer having a periodic structure.

31. The method of claim 29, wherein the act of forming the reflective layer comprises forming the reflective layer having a first sub-layer/second sub-layer periodic structure.

32. The method of claim 31, wherein the reflected light has a wavelength λ, and wherein the act of forming the reflective layer comprises forming the first sub-layer/second sub-layer structure with a period of approximately λ/4.

33. The method of claim 31, wherein the act of forming the reflective layer comprises forming the first sub-layer/second sub-layer structure with a period of approximately 175 nm.

34. The method of claim 29, wherein the act of forming the reflective layer comprises forming each of the first and second sub-layers of one of a semiconductor and dielectric material.

35. The method of claim 29, wherein the act of forming the reflective layer comprises forming each of the first sub-layers of SiₓGe₁₋ₓ and the at least one second sub-layer of Si.

36. The method of claim 35, wherein x is within the range of approximately 0.8 to approximately 0.95.

37. The method of claim 29, wherein the act of forming the reflective layer comprises forming each of the first sub-layers of SiO₂ and the at least one second sub-layer of Si.

38. The method of claim 29, wherein the act of forming the reflective layer comprises forming a plurality of second sub-layers.

39. The method of claim 29, wherein the act of forming the reflective layer comprises forming a Distributed Bragg Reflector mirror.

40. A method of forming a pixel cell, the method comprising:
alternately forming a plurality of layers of SiₓGe₁₋ₓ and a plurality of layers of Si, such that the plurality of SiₓGe₁₋ₓ layers are stacked alternately with the plurality of Si layers forming an SiₓGe₁₋ₓ/Si structure;
providing a semiconductor layer over the plurality of SiₓGe₁₋ₓ layers and the plurality of Si layers; and
forming a photo-conversion device at a surface of the semiconductor layer for receiving light reflected by the first and second reflective layers and for generating charge in response to the reflected light.

41. The method of claim 40, wherein the acts of forming the plurality of SiₓGe₁₋ₓ layers and the at least one Si layer comprises forming a periodic SiₓGe₁₋ₓ/Si structure with a period approximately equal to λ/4, where λ is a predetermined wavelength of the reflected light.

42. A method of forming a pixel cell, the method comprising:
alternately forming a plurality of layers of SiO₂ and a plurality of layers of Si, such that the plurality of SiO₂ layers are stacked alternately with the plurality of Si layers forming an SiO₂/Si structure;
providing a semiconductor layer over the plurality of SiO₂ layers and the plurality of Si layers; and
forming a photo-conversion device at a surface of the semiconductor layer for receiving light reflected by the first and second reflective layers and for generating charge in response to the reflected light.

43. The method of claim 42, wherein the acts of forming the plurality of SiO₂ layers and the at least one Si layer comprises forming a periodic SiO₂/Si structure with a period approximately equal to λ/4, where λ is a predetermined wavelength of the reflected light.
